(19) United States
(12) Patent Application Publication
(10) Pub. No.: US 2015/0307984 A1
(43) Pub. Date: Oct. 29, 2015

(54) EVAPORATION CELL

(71) Applicant: RIBER, BEZONS CEDEX (FR)

(72) Inventors: David ESTEVE, BOUGIVAL (FR); Franck STEMMELEN, VAUREAL (FR)

(21) Appl. No.: 14/694,164

(22) Filed: Apr. 23, 2015

(30) Foreign Application Priority Data
Apr. 24, 2014 (FR) 14 53687

(51) Int. Cl. C23C 14/24

(52) U.S. Cl. CPC C23C 14/243

(57) ABSTRACT

An evaporation cell for evaporating a material onto a substrate placed in a vacuum deposition chamber, includes an inner enclosure delimiting an evaporation chamber for receiving a crucible containing the material and having an opening for inserting the crucible into the evaporation chamber; evaporation elements placed at the periphery of the inner enclosure for placing the crucible in evaporation conditions; an injection duct for transporting a flow of vapour of the evaporated material from the evaporation chamber to an injector located in the vacuum deposition chamber; and a stop valve placed on the injection duct. The evaporation cell includes insertion opening/shutting elements that have an open configuration for inserting the crucible into the evaporation chamber, and a closed configuration for confining the evaporation chamber in communication with the vacuum deposition chamber via the injection duct, and opening elements to provide an evaporation opening in an envelope of the crucible.

### FIELD OF THE INVENTION

The invention relates to the field of evaporation and vacuum deposition of materials onto a substrate. The invention more particularly relates to an evaporation cell intended to evaporate a material, in order for the later to be deposited onto a substrate placed in a vacuum deposition chamber.

### BACKGROUND OF THE INVENTION

It is known from the document EP 1 825 018 a vacuum deposition apparatus including such an evaporation cell that is intended to evaporate a material, in order for the later to be deposited onto a substrate placed in a vacuum deposition chamber, and which includes:
an inner enclosure delimiting an evaporation chamber adapted to receive a crucible containing said material to be evaporated, this inner enclosure having an insertion opening for the insertion of the crucible into said evaporation chamber,
evaporation means placed at the periphery of said inner enclosure and adapted to place said crucible in evaporation conditions for the evaporation of the material contained in said crucible, when the latter is received in said evaporation chamber,
an injection duct adapted to transport a flow of vapour of the evaporated material from the evaporation chamber to an injector located in said vacuum deposition chamber, and
a stop valve placed on said injection duct.

Such a vacuum deposition apparatus allows to deposit a semi-conductor material or compound (for example: silicon, gallium arsenide, indium phosphide, etc.), an inorganic material (for example: selenium, antimony, phosphorus), or an organic material (for example: tris(8-hydroxyquinoline)aluminum (III) or Alq3, . . . ).

The evaporation cell of the document EP 1 825 018 allows, when the stop valve is closed, to connect the crucible to the injection duct without reaeration of the vacuum deposition chamber.

For that purpose, the crucible is a bottle whose mouth is adapted to be tightly screwed on a connector of the injection duct.

However, with the evaporation cell of the document EP 1 825 018, at the opening of the stop valve, a peak of pressure occurs, coming from the volume of air, imprisoned in the crucible and in the portion of the injection duct close to the connector, which escapes into the deposition chamber maintained under vacuum.

This peak of pressure may degrade the quality of the layer deposited on the substrate, so that the production yield is poor.

### SUMMARY OF THE INVENTION

So as to remedy the above-mentioned drawback of the state of the art, the present invention proposes an evaporation cell allowing to reduce, or even suppress, the peak of pressure at the time of loading of this evaporation cell with a full crucible.

For that purpose, the invention relates to an evaporation cell as mentioned hereinabove, which includes:
shutting means for shutting said insertion opening of the inner enclosure of the evaporation cell, such shutting means having:
   an open configuration allowing the insertion of said crucible into said evaporation chamber, and
   a closed configuration in which the evaporation chamber is confined and in communication with the vacuum deposition chamber via the injection duct when the stop valve is open, and
opening means adapted to provide an evaporation opening in an envelope of said crucible, which is filled with the material to be evaporated and maintained under vacuum before the opening, said evaporation opening allowing to place said crucible in communication with said evaporation chamber.

The evaporation cell according to the invention hence allows to change the crucible received in the evaporation chamber while limiting the intensity of the peak of pressure caused by the opening of the stop valve.

Indeed, the crucible having a tight envelope previously vacuumed and filled with the material to be evaporated hence significantly reduces the residual volume comprised between the inner enclosure of the evaporation cell and the envelope of the crucible that is imprisoned in the evaporation cell after insertion of the crucible into the evaporation chamber and after shutting of the insertion opening thanks to the shutting means.

Advantageously, the respective sizes of the evaporation chamber and of the crucible are adjusted so that this residual volume is lower than the inner volume of said crucible.

That way, the volume of air expelled at the insertion of the crucible into the evaporation chamber is low with respect to the total volume of the inner enclosure, so that the peak of pressure is reduced at the opening of the stop valve.

Also advantageously, the respective sizes of the evaporation chamber and of the crucible are adjusted so that the sum of the residual volume, comprised between said inner enclosure of the evaporation cell and said envelope of the crucible, and of the additional volume, delimited by the portion of the injection duct comprised between said evaporation chamber and said stop valve, is lower than the inner volume of said crucible.

Besides, other advantageous and non-limiting characteristics of the evaporation cell according to the invention are the followings:
said evaporation cell includes an outer enclosure enveloping said inner enclosure, said evaporation means, and said stop valve and having a passage opening opposite or merged with said insertion opening of the inner enclosure to allow the passage of said crucible for the insertion thereof into said evaporation chamber;
said shutting means for shutting the evaporation cell pass from their open configuration to their closed configuration upon the insertion of said crucible into said evaporation chamber;
said shutting means for shutting the evaporation cell comprise a closing plate provided with a gasket element intended to realize the tightness between said closing plate and said inner enclosure;
said opening means for opening the evaporation cell comprise a perforation needle intended to pierce a tight membrane seal of said vacuumed envelope of the crucible;
additional pumping means for pumping said inner enclosure are provided, which are adapted to vacuum said evaporation chamber;
exhausting means for exhausting said inner enclosure are provided, which are adapted to reaerate said evaporation chamber;
said evaporation cell further includes a loading chamber adjacent to the evaporation chamber for the engagement and the disengagement of said crucible into or from the evaporation chamber, said loading chamber being in communication with the evaporation chamber through said insertion opening;
heat shield means are also provided, which are interposed between said outer enclosure and said loading chamber and which are adapted to thermally isolate said evaporation chamber from said loading chamber.

### BRIEF DESCRIPTION OF THE DRAWINGS

Embodiments of the invention will be described in detail with reference to the appended drawings, in which:

FIG. 1 is a schematic sectional overall view in a vertical plane of a vacuum deposition apparatus including an evaporation cell according to a first embodiment of the invention;

FIG. 2 is a detailed view of the zone II of FIG. 1, showing the shutting means, the evaporation means of the evaporation cell of FIG. 1;

FIG. 3 is a schematic sectional view in a vertical plane of a full crucible before the engagement into the evaporation chamber of the evaporation cell of FIG. 1;

FIG. 4 is a schematic sectional view in a vertical plane of an evaporation cell according to a first variant in which a pump and a valve are connected to the evaporation chamber;

FIG. 5 is a schematic sectional view in a vertical plane of an evaporation cell according to a second variant in which the crucible includes a gasket intended to shut the insertion opening;

FIG. 6 is a schematic sectional view in a vertical plane of an evaporation cell according to a second embodiment of the invention, in which the evaporation cell further includes a loading chamber for the reloading of the crucibles.

### DETAILED DESCRIPTION OF THE INVENTION

In the following disclosure, the terms “top” and “bottom” will be used with reference to the vertical, in relation to the room in which the vacuum deposition apparatus is installed, the top referring to the side directed towards the ceiling of the room and the bottom referring to the side directed towards the floor. Likewise, the terms “lower” and “upper” will refer to the sides directed towards the bottom and the top, respectively.

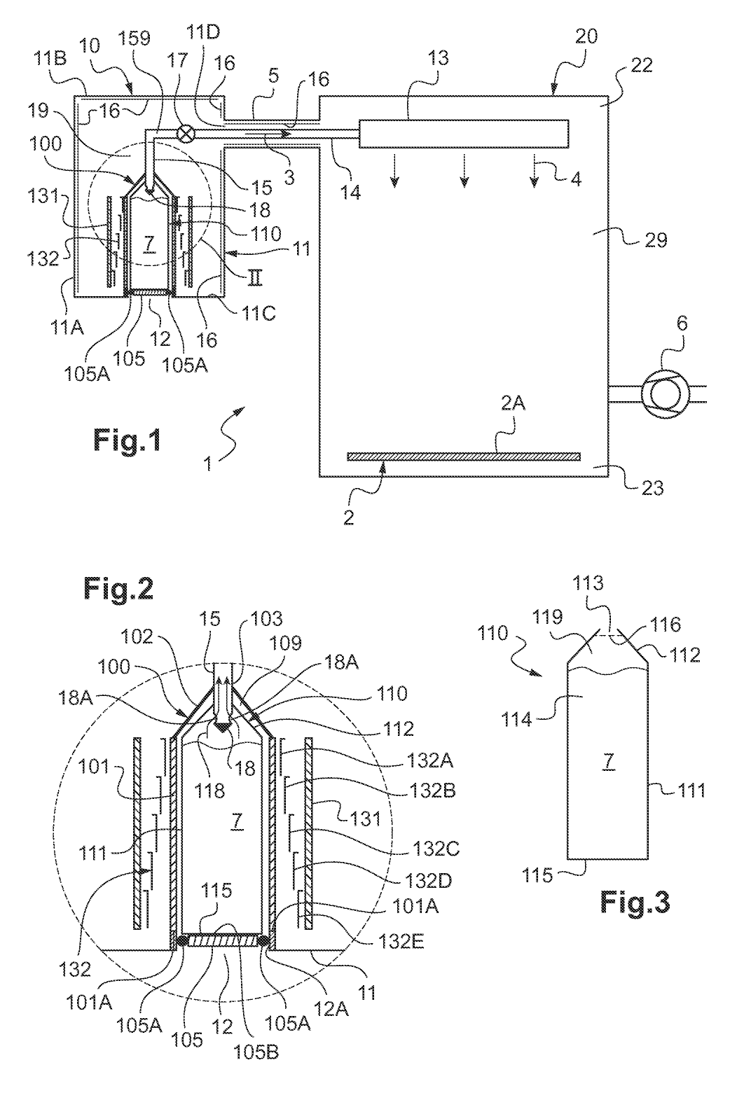

FIG. 1 shows a schematic sectional overall view in a vertical plane of a vacuum deposition apparatus 1, which includes, on the one hand, an evaporation cell 10, and on the other hand, a vacuum deposition chamber 20.

Generally, the evaporation cell 10 of the vacuum deposition apparatus 1 is intended to evaporate a material 7, in order for the latter to be deposited onto a substrate 2 placed in the vacuum deposition chamber 20, here in a bottom part 23 of the latter.

It will be seen hereinafter that the evaporation cell 10 is adapted to generate an upstream flow of vapour 3 of said material 7, which upstream flow of vapour 3 is transported by an injection duct 14 from the evaporation cell 10 to an injector 13 located in the top part 22 of the vacuum deposition chamber 20.

The evaporation cell 10 and the vacuum deposition chamber 20 are connected to each other by a tubular connector 5 passed through by the injection duct 14.

The injector 13 of the evaporation cell 10 injects the vapour of material 7 transported by the injection duct 14 into the vacuum deposition chamber 20 as a downstream flow of vapour 4 directed downward towards the substrate 2, so that the material 7 is deposited onto an upper face 2A of the substrate 2 directed towards the injector 13.

It is also conceivable that the downstream flow of vapour goes upwards and is deposited onto a lower face of the substrate.

The injector 13 is adapted to optimize the characteristics of the downstream flow of vapour 4 directed towards the substrate 2, for example the flow rate or the spatial distribution thereof, so that the layer of material 7 deposited on the upper face 2A of the substrate 2 has the required properties, such as the thickness, the state of surface, the conductivity, etc . . . , as a function of the intended application.

Inside the injector 13 are provided specific heating means (not shown), intended to avoid the condensation of the vapours of material 7 inside the injector 13, which could compromise the good operation thereof.

In order to make and maintain the vacuum inside the vacuum deposition chamber 20, the vacuum deposition apparatus 1 includes pumping means 6 connected to the vacuum deposition chamber 20, whose pumping capacities are adjusted as a function of the inner volume 29 of the vacuum deposition chamber 20.

These pumping means 6 herein comprise a turbo-molecular pump or a cryogenic pump, which lowers the level of pressure inside the vacuum deposition chamber 20 down to 10⁻³ to 10⁻⁸ Torr.

A first embodiment of evaporation cell 10 intended to produce a downstream flow of vapour 3 towards the injector 13 will now be described with reference to FIGS. 1 to 5.

As shown in FIG. 1, the evaporation cell 10 of the vacuum deposition apparatus 1 first includes an outer enclosure 11, herein of generally cylindrical shape, comprising a lateral wall 11A, an upper wall 11B (or “roof”), and a lower wall 11C (or “bottom”).

On the inner faces of the lateral wall 11A and of the upper wall 11B of the outer enclosure 11, and also of the tubular connector 5, are provided heating elements, for example heating resistances 16, intended to heat substantially homogeneously the inner volume 19 of the outer enclosure 11, in particular the injection duct 14, so as to avoid that the vapours of material 7 are condensed on the cold parts of the evaporation cell 10.

On the outer faces of the lateral wall 11A, of the upper wall 11B, of the lower wall 11C, and also of the tubular connector 5, are provided cooling elements (not shown), for example cold water coils, so that the outer enclosure 11 of the evaporation cell 10 is cold to the touch from the outside.

Between the heating elements 16 and the cooling elements is inserted a radiative shield, for example made as a refractory material, so that the heating and the cooling are each independently efficient.

The lateral wall 11A comprises an opening 11D from which the tubular connector 5 extends outwardly for the connection of the evaporation cell 10 with the vacuum deposition chamber 20 of the vacuum deposition apparatus 1.

In this configuration, the outer enclosure 11 and the vacuum deposition chamber 20 are in communication with each other and share the same vacuum, so that when the vacuum is made inside the vacuum deposition chamber 20, it is also made inside the outer enclosure 11 of the evaporation cell 10. The level of pressure in this outer enclosure 11 is hence equal to that in the vacuum deposition chamber 20.

As a variant, a tight weld can be provided between the tubular connector and the injection duct of the evaporation cell, so that the outer enclosure of the evaporation cell does not share the same vacuum as the vacuum deposition chamber. In this case, the evaporation cell then comprises an enclosure pump that is dedicated thereto and that is intended to pump the inner volume of the outer enclosure to make the pressure fall down to a level of the order of 10⁻³ to 10⁻⁸ Torr.

As can be seen in FIGS. 1, 2, 4 and 5, an opening, called hereinafter passage opening 12, is formed in the lower wall 11C of the outer enclosure 11.

This passage opening 12 has an inner edge 12A, which is herein circular in shape, above which extends, towards the inside of the outer enclosure 11, an evaporation chamber of the evaporation cell 10.

This evaporation chamber is delimited by an inner enclosure 100 comprising, on the one hand, a cylindrical body 101 coaxial to the passage opening 12, and on the other hand, a truncated neck 102 continuing the body 101, up to an upper edge 103 of the inner enclosure 100.

This inner enclosure 100 that, as well shown in FIG. 1, is enveloped by the outer enclosure 11 of the evaporation cell 10, has an insertion opening that is herein merged with the passage opening 12 of the outer enclosure 11.

As a variant, the passage opening of the outer enclosure and the insertion opening of the inner enclosure may be distinct from each other and then opposite to each other.

This body 101 of the evaporation chamber 100 has a lower edge 101A, which extends with no interruption along the lower edge 12A of the passage opening 12 (see FIG. 2). The lower edge 101A is tightly fixed to the lower wall 11C of the outer enclosure 11 of the evaporation cell 10, so that the inner volume 19 of the outer enclosure 11 of the evaporation cell 10 does not communicate with the inner volume 109 of the evaporation chamber 10.

The upper edge 103 of the inner enclosure 100 is tightly connected to an upstream portion 15 of the injection duct 14 of the evaporation cell 10, herein forming a bend at the upper edge 103. This upstream portion could also be a straight connector, with no bend.

The tight connection can be made, for example, by means of a welding.

The evaporation chamber 100 of the evaporation cell 10 is intended to receive a crucible 110 containing the material 7 to be evaporated.

This crucible 110 has generally the shape of a bottle and has adapted sizes so as to be able to be received in the evaporation chamber 100.

The crucible 110 comprises a lateral wall 111 that is closed downward by a bottom 115 and that narrows upward into a neck 112 delimiting an opening 113 of the crucible 110.

The crucible 110 is preferably made single part from a material having a good heat conductivity and a resistance to high temperatures. It may for example be made of a ceramic material such as pyrolytic boron nitride or PBN, or a material of the vitreous type such as quartz.

The crucible 110 is intended to be filled with the material 7 to be evaporated, wherein the material 7 can be in liquid form, powder form, or even in an ingot form.

Before use, the crucible 110 is herein sealed by means of a membrane seal 116 that is located close to the opening 113 of the crucible 110 and that tightly closes the crucible 110.

It will be seen hereinafter that this membrane seal 116 is intended to be pierced so as to let the vapours of the evaporated material 7 escape when the crucible 110 is placed in conditions of evaporation.

Before opening of this membrane seal 116, the bottom 115, the body 111, the neck 112 and the membrane seal 116 hence form a sealed envelope of the crucible 110 that is filled with the material 7 to be evaporated. This envelope, after filling of the crucible 110 with the material 7, is then vacuumed and closed by the membrane seal 116 so that the inner volume 119 of the crucible, left free, is maintained, before the opening, at a pressure comprised between 10⁻¹ and 10⁻³ mbar.

Such a vacuuming of the crucible 110 allows in particular to avoid the degradation of the material 7 contained in the crucible 110, for example at the time of filling of the latter with an organic material that may oxide upon contact with oxygen or with water contained in ambient air.

It will also be seen that the vacuum of the crucible 110 also allows to limit the peak of pressure in the vacuum deposition chamber 20 when the membrane seal 116 is pierced.

In order to place in conditions of evaporation a crucible 110 engaged with the evaporation chamber 100, the evaporation cell 10 also includes evaporation means arranged at the periphery of the evaporation chamber 100 receiving the crucible 110 so that, herein, the outer enclosure 11 envelops these evaporation means.

In all the embodiments and the variants thereof described in FIGS. 1 to 6, these evaporation means first comprise electric resistances 131 surrounding the evaporation chamber 100 and extending from the bottom 11C of the outer enclosure 11, substantially parallel to the body 101 of the evaporation chamber 100, up to the neck 102 of the latter.

These electric resistances 131 are power supplied and heated at high temperature so that they radiate heat, essentially as infrareds.

As a variant, the evaporation means may comprise infrared lamps placed directly in the inner volume of the evaporation chamber, against the body of the latter, so as to irradiate directly the crucible engaged in the evaporation chamber.

The evaporation means also comprise a heat shield 132 located inside the outer enclosure 11 and interposed between the body 101 of the evaporation chamber 100 and the electric resistances 131.

As well shown in FIG. 2, this heat shield 132 is of “telescopic” type and herein includes five mobile elements 132A, 132B, 132C, 132D, 132E, cylindrical and coaxial to each other, which may nest into each other so that the height of the heat shield 132 can be adjusted at will.

For example, FIG. 2 shows the heat shield 132 in its greatest height, when all the mobile elements 132A, 132B, 132C, 132D, 132E are extended.

The mobile elements 132A, 132B, 132C, 132D, 132E are herein formed of cylinders made of the same material, for example a metal material, such as steel or aluminium.

As a variant, the mobile elements may for example be consisted of cylinders made of quartz, glass or silica, whose outer face directed towards the electric resistances is coated with a layer reflecting the heat radiation emitted by these electric resistances, for example a metal layer, such as a layer of silver, aluminium or gold.

The evaporation means moreover include operation means (not shown) allowing to slide the mobile elements 132A, 132B, 132C, 132D, 132E with respect to each other to adjust the height of the heat shield 132.

Although in FIGS. 1, 2 and 4 to 6, the mobile elements 132A, 132B, 132C, 132D, 132E are five in number and have all the same height, it can be contemplated as a variant that the evaporation means comprise more or less mobile elements and that these latter be of different heights. This can be advantageous in particular to adapt the height of the heat shield to the height of the evaporation chamber and to adjust this height with more or less accuracy.

The evaporation means finally include herein the cylindrical body 101 of the evaporation chamber 100, which has a transparent wall that is chosen so as to transmit the infrared radiation emitted by the electric resistances 131.

In the conditions of pressure inside the outer enclosure 11, the heat exchanges between the electric resistances 131 and the body 111 of a crucible 110 engaged with the evaporation chamber 100 essentially occur by radiation, because the convection exchanges are strongly limited due to the vacuum inside the outer enclosure 11.

When a crucible 110 is engaged with the evaporation chamber 110 (see FIG. 2 for example), i.e. when it is received inside the inner volume 109 of the evaporation chamber 100, the lateral wall 111 thereof is then opposite the body 101 of the evaporation chamber 100, i.e. opposite the transparent wall of the inner enclosure.

The transparent wall may for example be formed of a hollow cylinder made of quartz, glass or silica, possibly coated with a layer improving the infrared transmission of the transparent wall.

The heat shield 132, arranged between the electric resistances 131 and this transparent wall of the body 101 of the evaporation chamber 100, will hence act as a mirror for the infrared light radiated by the electric resistances 131 towards the body 111, 121 of a crucible 110, 120 located in the evaporation chamber 100.

Hence, thanks to the heat shield 132, it is possible to uncover all or part of the electric resistances 131, so that only the fraction of material 7 contained in the upper part 114 of the crucible 110 (see FIG. 3) be subjected to the radiation emitted by the electric resistances and be heated, as a function of the pressure in the evaporation chamber 100, up to a sufficient heating temperature to allow the evaporation thereof.

Moreover, thanks to the operation means sliding the mobile elements 132A, 132B, 132C, 132D, 132E, it is possible to finely adjust the height of the heat shield 132 to adjust in real time the flow of vapour 118 (see the arrows in FIG. 2) in the upstream portion 15 of the injection duct 14.

In particular, it is possible to obtain conditions of evaporation in which the flow of vapour 118 remains substantially constant all along the evaporation of the material 7 contained in the crucible 110. This reveals to be particularly interesting for the deposition of a uniform layer on the substrate 2 placed in the vacuum deposition chamber 20.

As shown in FIGS. 1, 2, 4 and 5, the evaporation cell 10 also includes a stop valve 17 placed on the injection duct 14 of the evaporation cell 10.

Preferably, this stop valve 17 placed on the injection duct 14 so as to be located inside the outer enclosure 11 of the evaporation cell 10 that envelops it.

That way, the stop valve 17 is heated by the heating resistances 16 arranged on the inner faces of the outer enclosure 11 so as to limit the condensation of the vapours of evaporated material 7 onto this stop valve 17.

The stop valve 17 may for example be a tight “all or nothing” valve with two open and closed positions, which allows, in the closed position, when the evaporation chamber 100 is empty, to avoid that the flow of vapour comes back towards the evaporation chamber 100 so as to condensate on the body 101 of the inner enclosure 100, which may reduce the efficiency of the evaporation means to heat the crucible 110.

Generally, the stop valve 17 firstly serves to isolate the vacuum deposition chamber 20 from the evaporation chamber 100 of the evaporation cell 10, when this evaporation chamber 100 is open and aerated. That way, thanks to the stop valve 17, it is in particular possible to change of crucible without reaerating the vacuum deposition chamber 20 of the vacuum deposition apparatus 1. A high level of vacuum is kept in the vacuum deposition chamber 20, and any pollution of the latter or of a substrate that would be located therein is hence avoided.

Advantageously, it may be provided to place a control valve in series on the injection duct 14, downstream the stop valve 17.

Although the flow rate of the flow of vapour at the outlet of the evaporation chamber 100 is adjusted thanks to the evaporation means, this control valve may also allow to adjust more finely the flow rate of vapour of the material 7.

According to the invention, so as to avoid a reaeration of the vacuum deposition chamber 20 and to limit the peak of pressure during the change of crucible in the evaporation chamber 100, the evaporation cell 10 further includes shutting means for shutting the insertion opening 12 of the inner enclosure 100 and opening means for opening the crucible 110 allowing to form an evaporation opening in the sealed envelope of the crucible 110 maintained under vacuum.

For that purpose, the shutting means have an open configuration allowing the insertion of said crucible into said evaporation chamber 100, and a closed configuration in which the evaporation chamber 100 is confined.

As schematically shown in FIG. 1 and in more detail in FIG. 2, the shutting means herein include a circular closing plate 105 comprising at its periphery a sealing gasket 105A.

This closing plate 105 has shape and size that are adapted to the passage opening 12 of the outer enclosure 11 and to the insertion opening 12 of the inner enclosure 100 so that it can engage into these latter with the gasket 105A bearing on the inner edge 12A of the insertion opening 12, hence closing tightly the evaporation chamber 100 with respect to the outside.

The closing plate 105 is then in its closed configuration. When the stop valve 17 is open, the evaporation chamber 100 is then confined and in communication only with the vacuum deposition chamber 20 via the injection duct 14. As used herein, the term “confined” means that the evaporation chamber 100 is not in communication with the outside of the evaporation cell 10 in which the pressure is close to the atmospheric pressure (1 bar).

Locking means (not shown) are also provided, which allow to keep the closing plate 105 in position after engagement into the insertion opening 12.

A back-plate may for example be fixed to the lower wall 11C of the outer enclosure 11 of the evaporation cell 10, whose upper face would bear against the lower face of the closing plate 105 so as to prevent that the latter disengages itself from the insertion opening 12.

Advantageously herein, the closing plate 105 allows to also support the crucible 110 when the latter is engaged with the evaporation chamber 100. More precisely, when the crucible 110 is received in the inner enclosure 100 of the evaporation cell 10, its bottom 115 rests on the upper face 1058 of the closing plate 105 (see FIG. 2).

In variants, specific holding means can be provided, which are intended to maintain the crucible in position in the evaporation chamber after the insertion thereof into the latter.

For example, the closing plate can be maintained in position by means of a piston. It can also be provided that the closing plate comprises on its peripheral edge a screw thread adapted to cooperate with an internal screw thread made in the inner edge of the passage opening. In this case, the assembly and holding in position would then be performed by screwing the closing plate into the insertion opening 12.

As schematically shown in FIG. 1 and in more detail in FIG. 2, the opening means for opening the evaporation cell 10 herein include a perforation needle 18 located at the end of the upstream portion 15 of the injection duct 14 located in the evaporation chamber 100.

The perforation needle 18 is herein integral with this upstream portion 15, but it can be provided as a variant that this perforation needle is formed of a part added on the upstream portion, for example by screwing or by force fitting.

This perforation needle 18 is intended to pierce the tight membrane seal 116 of the vacuumed envelope of the crucible 110. The membrane seal 116 is then adapted to be broken at the time of introduction of the crucible 110 in the evaporation chamber 100. For example, the membrane seal 116 of the crucible 100 may be formed by a thin membrane made of glass, or quartz, offering, when not pierced, a sufficient tightness of the envelope of the crucible 110.

Thanks to the pointed shape of the perforation needle 18 and to the force exerted by the latter on the membrane seal 116, the latter is broken so that an exhaust opening is formed in the envelope of the crucible 110.

The evaporation opening hence allows to place the crucible 110 in communication with the evaporation chamber 100.

More precisely, the evaporation opening places the inner volume 119 of the crucible 110 in communication with the injection duct 14 of the evaporation cell 10, through herein two exhaust holes 18A that are formed in the upstream portion 15 of the injection duct 14, just above the perforation needle 18 and that, after engagement of the crucible 110 into the evaporation chamber 110, are located in the inner volume 119 of said crucible 110.

That way, during the evaporation of the material 7 contained in the crucible 110 heated by the evaporation means 131, 132, the flow of vapour 118 generated in the crucible 110 is led into the upstream portion 15 of the injection duct 14 via these exhaust holes 18A.

An exemplary embodiment of the vacuum deposition apparatus 1 will now be described in detail using this first embodiment of the evaporation cell 10. This will allow to understand the advantages of such an evaporation cell 10 and in particular the interest thereof for reducing the peaks of pressure during the changes of crucible.

At the beginning of the deposition method, the substrate 2 being placed in the lower part 23 of the vacuum deposition chamber 20, the stop valve 17 of the evaporation cell 10 is closed, if not already closed. In this configuration, the inner volume 29 of the vacuum deposition chamber 20 and the inner volume 19 of the outer enclosure 11 of the evaporation cell 10 are in communication with each other but are isolated from the inner volume 109 of the evaporation chamber 100, thanks to the stop valve 17. The pumping of the vacuum deposition chamber 20 and of the outer enclosure 11 is then performed thanks to the pump 6, until the pressure reaches a level comprised between 10⁻³ and 10⁻⁸ Torr.

In parallel to this pumping, the heating resistances 16 of the outer enclosure 11 are powered on so as to heat the stop valve 17, the injection duct 14 and its upstream portion 15 up to a temperature comprised between 15° C. and 500° C.

The evaporation means 131, 132 are also powered on so as not to create a too important gradient of temperature inside the evaporation cell 10.

A first crucible 110 containing the material 7 to be evaporated is also prepared, with its envelope vacuumed and sealed thanks to the membrane seal 116.

When the required level of pressure is reached in the vacuum deposition chamber 20 and when the different elements of the evaporation cell 10 have been heated up to the required level of temperature, the engagement of the first crucible 110 into the evaporation chamber 100 can then be performed.

For that purpose, the crucible 110 is passed through the passage opening 12 of the outer enclosure 11, herein merged with the insertion opening 12 of the inner enclosure 100, to introduce upwards the crucible 110 into the evaporation chamber 100.

This introduction is performed preferably by means of the closing plate 105 on which the crucible 110 rests. That way, when the membrane seal 116 comes to be broken by the perforation needle 18 due to the introduction of the crucible 110 into the inner enclosure 100, the closing plate 105, thanks to its peripheral joint 105A, shuts in closed configuration the insertion opening 12 of the evaporation chamber 100.

Hence, the only quantity of air at ambient pressure imprisoned during the engagement of the crucible 110 with the evaporation chamber 100 is that which is comprised in the residual volume 109 comprised between the inner enclosure 100 of the evaporation cell 10 and the envelope of the crucible 110 (see FIG. 2 for example) received in the evaporation chamber 100.

Preferably, according to the invention, the respective sizes of the evaporation chamber 100 and of the crucible 110 are adjusted so that this residual volume 109 is lower than the inner volume 119 of the crucible 110.

That way, it is made sure that the pressure in the residual volume 109 and in the additional volume 159 delimited by the upstream portion 15 of the injection duct 14 comprised between the evaporation chamber 100 and the stop valve 17 (see FIG. 1) is the closest possible to that in the crucible 110 before perforation of the membrane seal 116.

Hence, at the opening of the stop valve 17, the peak of pressure is limited.

Advantageously, the stop valve 17 may be placed the closest possible to the evaporation chamber 100 so as to limit the additional volume 159.

Still more preferentially, the respective sizes of the evaporation chamber 100 and of the crucible 110 are adjusted so that the sum of the residual volume 109 and of the additional volume 159 is lower than the inner volume 119 of the crucible 110.

That way, the peak of pressure is still more limited.

After engagement of the crucible 110, the latter is placed in conditions of evaporation thanks to the electric resistances 131 and to the heat shield 132 so as to generate a flow of vapour 118 in the injection duct 14.

The stop valve 17 can then be open so as to let the upstream flow of vapour 3 (see FIG. 1) flow up to the injector 13 that diffuses the downstream flow of vapour 4 towards the substrate 2 placed in the vacuum deposition chamber 20 to deposit the evaporated material 7 on the upper surface 2A of the substrate 2.

When the first crucible 110 is empty following the full evaporation of the material 7, the stop valve 17 is closed so as to isolate the vacuum deposition chamber 20 from the evaporation chamber 100 and to avoid the reaeration thereof. The first crucible 110 can then be removed and replaced by a full crucible according to the same method.

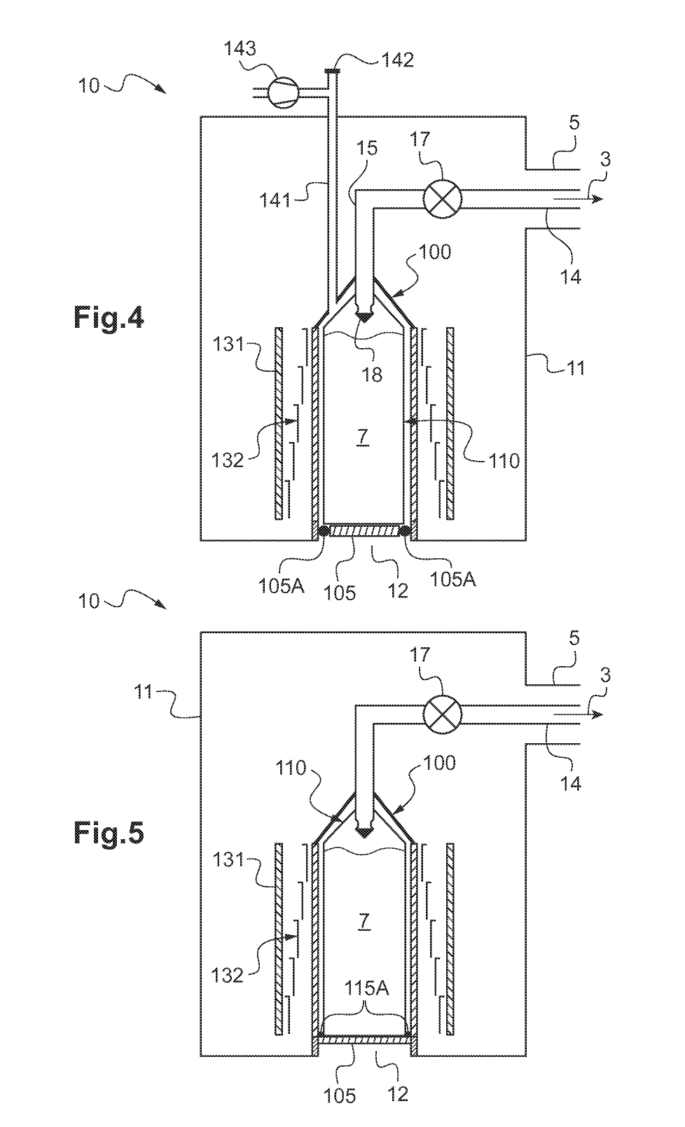

Advantageously, in a variant of the evaporation cell 10 shown in FIG. 4, it can be provided an additional pump 143 of the inner enclosure 100, which is for example connected to the latter by means of a connection pipe 141 branched on the neck 102 of the inner enclosure 100.

This additional pump 143 allows to vacuum the evaporation chamber 100 before the opening of the stop valve 17, to still reduce the peak of pressure.

In another variant, shown herein in FIG. 4 in combination with the previous one, without this being limiting, it can be provided an exhaust valve 142 of the inner enclosure 100 that is herein mounted on the connection pipe 141, as a derivation of the additional pump 143.

This exhaust valve allows to reaerate the evaporation chamber 100 before the disengagement of the crucible 110 so that this disengagement is made easier.

In still another variant of the first embodiment shown in FIG. 5, it can be provided a crucible 110 comprising in its low part, close to its bottom 115, a peripheral joint 115A intended to realise the tightness of the evaporation chamber 100. In this case, the shutting means then comprise said peripheral joint 115A of the crucible 110 as well as a closing plate herein intended to lock and maintain the crucible 110 in position in the evaporation chamber 100.

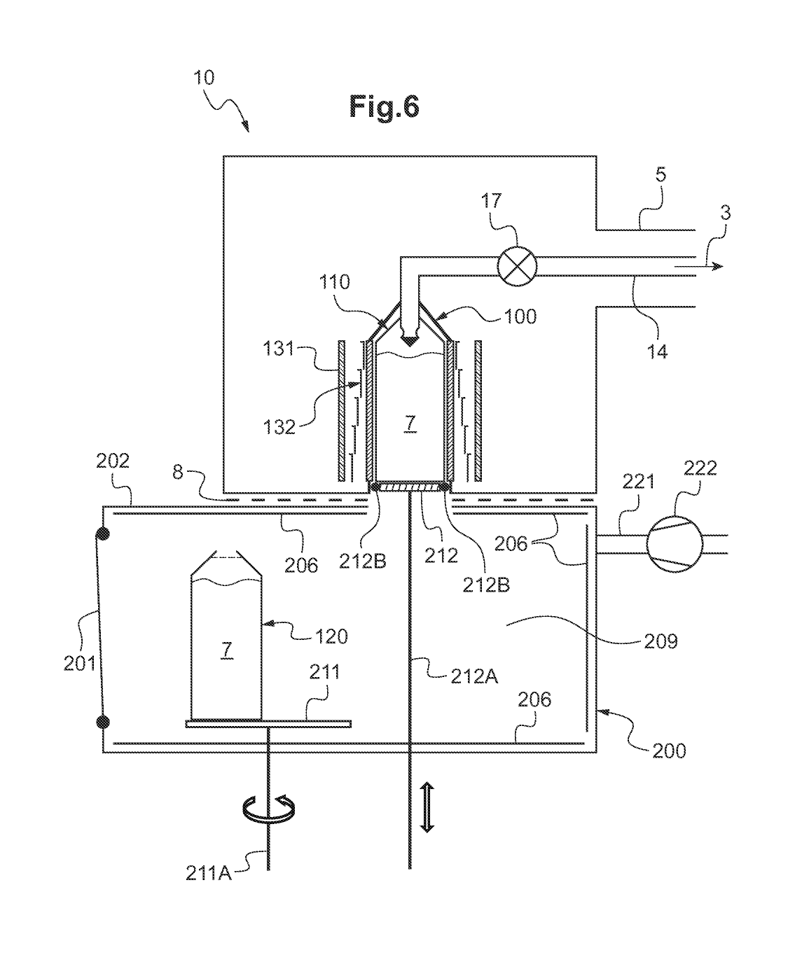

In a second embodiment of evaporation cell 10, shown in FIG. 6, the evaporation cell 10 further includes a loading chamber 200 adjacent to the evaporation chamber 100 for the engagement and the disengagement of the first crucible 110 into/from the evaporation chamber 100.

This loading chamber 200 herein comprises in particular a confining enclosure 202 and a trap door 201 allowing the introduction of the crucibles into this confining enclosure 202.

Like for the outer enclosure 11 of the evaporation cell 10, it can be provided, on the inner faces of the confining enclosure 202, heating elements, for example heating resistances 206, intended to heat substantially homogeneously the inner volume 209 of the loading enclosure, and in particular the different elements that may be therein, as the crucibles 110, 120.

The confining enclosure 202 of the loading chamber 200 comprises on its upper wall an opening located opposite the insertion opening 12 carrying the evaporation chamber 100, so that the loading chamber 200 is in communication with the evaporation chamber 100 through this insertion opening 12 when the latter is not shut.

The loading chamber 200 moreover includes an additional pump 222 branched on the confining enclosure 202 via a pumping duct 221 to vacuum said loading chamber 200, for example when the latter has been reaerated by the opening of the trap door 201.

In the loading chamber 200, it is moreover provided means for loading and unloading the crucibles 110, 120, herein a carrousel and piston system.

More precisely, the loading chamber 200 firstly comprises a piston 212A at the upper end of which is fixed a plate 212 intended to receive the first crucible 110 or the second crucible 120.

The piston 212A is mobile in vertical translation, so that the plate 212 can go up and down along the axis of the piston 212A, between:
a “low” position in which the plate 212 is close to the lower wall of the confining enclosure 202, and
a “high” position (case of FIG. 6) in which the plate 212 is located at the insertion opening 12 of the evaporation cell 10.

The low position allows the loading or unloading of the plate 212 with a crucible 110, 120.

Once the crucible 110 in place on the plate 212, the latter can go up vertically thanks to the piston 212A and hence engage the crucible 110 with the evaporation chamber 100, by passing through the insertion opening 12 of the evaporation cell 10.

The loading chamber 200 also includes a carrousel 211 mounted in the loading chamber 200 so as to turn around an axis of rotation 211A allowing to drive the carrousel 211 into rotation.

This carrousel 211 is intended to receive the crucibles for the loading and unloading thereof onto and from the plate 212.

The angular position of the carrousel 211 is controlled by a motor (not shown) piloted to successively carry each of the crucibles 110, 120 loaded on the plate 212 opposite the plate 212 and the operating piston 212A thereof.

The carrousel 211 and plate 212 system is particularly advantageous because it offers a reduced size for a given number of crucibles. Hence, the size of the loading chamber 200 and the pumping capacities of the additional pump 222 connected to the loading chamber 200 can be limited.

Heat shielding means are provided, which are interposed between the outer enclosure 11 of the evaporation cell 10 and the loading chamber 200.

More precisely, these heat shielding means herein comprise a connection flange 8 allowing the attachment of the lower wall 11C of the outer enclosure 11 to the upper wall of the loading chamber 200. This connection flange 8 herein includes a coil network in which circulates a cooling liquid (water, nitrogen, etc . . . ).

This connection flange 8 allows in particular to thermally isolate the evaporation chamber 100 from the loading chamber 200 and to avoid that the heat emitted by the different heating means 16 of the evaporation cell 10 has a disturbing effect on a crucible 110, 120 placed in the loading chamber 200, and vice versa so as not to the disturb the thermal gradient in the crucible 110, 120 during evaporation.

That way, it is possible to remove the first crucible 110 from the evaporation chamber 100, “under hot conditions”, when it is hot, without waiting for the cooling thereof. The second crucible 120 can then be introduced into the evaporation chamber 100 as soon as the first crucible 110 has been removed, and the evaporation can be resumed as soon as this second crucible 120 is at temperature.

Moreover, thanks to the heat shielding means 8, it is possible to load the second crucible 120 into the loading chamber 200 while the first crucible 110 is in course of evaporation, and this despite the heat emitted by the evaporation means 131, 132 that heat the first crucible 110. This heat emitted has no noticeable and harmful thermal effect on the second crucible 120 located in the loading chamber 200. In particular, the temperature of the material 7 to be evaporated present in the crucible 120 remains lower than the temperature of evaporation of the material 7.

In this second embodiment, the shutting means for shutting the insertion opening 12 are hence formed by the plate 212 provided with its peripheral gasket 212B, as the gasket 105A of the closing plate 105.

One of the main advantages of such an evaporation cell 10 is that, thanks to the use of the loading chamber 200, during the engagement of a new crucible into the evaporation chamber 100, the air imprisoned in the inner enclosure 100 with the crucible 110, 120 may be a pressure far lower than the atmospheric pressure, thanks in particular to the additional pump that would have vacuumed the confining enclosure 202 before the introduction of the crucible in the evaporation chamber 100.

Another advantage of the use of an evaporation cell 10 with a loading chamber 200 is that the times of interruption of the deposition method are reduced because the reloading of the loading chamber 200 can be made during the evaporation of a crucible engaged with the evaporation chamber 100 and that a previous placement in conditions of evaporation of the crucibles loaded in the loading chamber 200 can be made thanks to the heating resistances 206. That way, a flow of vapour is more rapidly obtained after engagement of the crucible into the evaporation chamber 100.

Finally, the times of interruption may even be fully suppressed using an evaporation cell including several evaporation chambers each provided with their respective stop valve.

That way, an empty crucible may be replaced whereas a crucible still filled with material is in course of evaporation.

1. An evaporation cell (10) intended to evaporate a material (7), in order for the later to be deposited onto a substrate (2) placed in a vacuum deposition chamber (20), including:
an inner enclosure delimiting an evaporation chamber (100) adapted to receive a crucible (110) containing said material (7) to be evaporated, this inner enclosure (100) having an insertion opening (12) for the insertion of the crucible (110) into said evaporation chamber (100),
evaporation means (101, 131, 132) placed at the periphery of said inner enclosure (100) and adapted to place said crucible (110) in evaporation conditions for the evaporation of the material (7) contained in said crucible (110), when the latter is received in said evaporation chamber (100),
an injection duct (14) adapted to transport a flow of vapour (3) of the evaporated material (7) from the evaporation chamber (100) to an injector (13) located in said vacuum deposition chamber (20), and
a stop valve (17) placed on said injection duct (14), characterized in that it includes:
shutting means (105, 105A) for shutting said insertion opening (12) of the inner enclosure (100) of the evaporation cell (10), such shutting means (105, 105A) having:
an open configuration allowing the insertion of said crucible (110) into said evaporation chamber (100), and
a closed configuration in which the evaporation chamber (100) is confined and in communication with the vacuum deposition chamber (20) via the injection duct (14) when the stop valve (17) is open, and
opening means (18) adapted to provide an evaporation opening in an envelope (111, 112, 115, 116) of said crucible (110), which is filled with the material (7) to be evaporated and maintained under vacuum before the opening, said evaporation opening allowing to place said crucible (110) in communication with said evaporation chamber (100).

2. The evaporation cell (10) according to claim 1, wherein, when said insertion opening (12) is shut by the shutting means (105, 105A) in closed configuration and when, after insertion, said crucible (110) is received in said evaporation chamber (100), the respective sizes of said evaporation chamber (100) and of said crucible (110) are adjusted so that the residual volume (109) comprised between said inner enclosure (100) of the evaporation cell (10) and said envelop of the crucible (110) is lower than the inner volume (119) of said crucible (110).

3. The evaporation cell (10) according to claim 1, wherein, when said insertion opening (12) is shut and said crucible (110) is received in said evaporation chamber (100), the respective sizes of said evaporation chamber (100) and of said crucible (110) are adjusted so that the sum of the residual volume (109), comprised between said inner enclosure (100) of the evaporation cell (10) and said envelop of the crucible (110), and of the additional volume (159), delimited by the portion of the injection duct (14) comprised between said evaporation chamber (100) and said stop valve (17), is lower than the inner volume (119) of said crucible (110).

4. The evaporation cell (10) according to claim 1, including an outer enclosure (11) enveloping said inner enclosure (100), said evaporation means (101, 131, 132) and said stop valve (17), and having a passage opening opposite or merged with said insertion opening (12) of the inner enclosure (100) to allow the passage of said crucible (110) for the insertion thereof in said evaporation chamber (100).

5. The evaporation cell (10) according to claim 1, wherein said shutting means (105, 105A) for shutting said evaporation cell (10) pass from their open configuration to their closed configuration upon the insertion of said crucible (110) into said evaporation chamber (100).

6. The evaporation cell (10) according to claim 1, wherein said shutting means (105, 105A) for shutting said evaporation cell (10) comprise a closing plate (105) provided with a gasket element (105A) intended to realize the tightness between said closing plate (105) and said inner enclosure (100).

7. The evaporation cell (10) according to claim 1, wherein said opening means (18) for opening said evaporation cell (10) comprise a perforation needle (18) intended to pierce a tight membrane seal (116) of said vacuumed envelope of the crucible (110).

8. The evaporation cell (10) according to claim 1, wherein additional pumping means (141, 143) for pumping said inner enclosure (100) are provided, which are adapted to vacuum said evaporation chamber (100).

9. The evaporation cell (10) according to claim 1, wherein exhausting means (141, 142) for exhausting said inner enclosure (100) are provided, which are adapted to reaerate said evaporation chamber (100).

10. The evaporation cell (10) according to claim 1, further including a loading chamber (200) adjacent to the evaporation chamber (100) for the engagement and the disengagement of said crucible (110) into/from the evaporation chamber (100), said loading chamber (200) being in communication with the evaporation chamber (100) through said insertion opening (12).

11. The evaporation cell (10) according to claim 10, wherein heat shield means (8) are also provided, which are interposed between said outer enclosure (11) and said loading chamber (200) and which are adapted to thermally isolate said evaporation chamber (100) from said loading chamber (200).

12. The evaporation cell (10) according to claim 2, including an outer enclosure (11) enveloping said inner enclosure (100), said evaporation means (101, 131, 132) and said stop valve (17), and having a passage opening opposite or merged with said insertion opening (12) of the inner enclosure (100) to allow the passage of said crucible (110) for the insertion thereof in said evaporation chamber (100).

13. The evaporation cell (10) according to claim 2, wherein said shutting means (105, 105A) for shutting said evaporation cell (10) pass from their open configuration to their closed configuration upon the insertion of said crucible (110) into said evaporation chamber (100).

14. The evaporation cell (10) according to claim 2, wherein said shutting means (105, 105A) for shutting said evaporation cell (10) comprise a closing plate (105) provided with a gasket element (105A) intended to realize the tightness between said closing plate (105) and said inner enclosure (100).

15. The evaporation cell (10) according to claim 2, wherein said opening means (18) for opening said evaporation cell (10) comprise a perforation needle (18) intended to pierce a tight membrane seal (116) of said vacuumed envelope of the crucible (110).

16. The evaporation cell (10) according to claim 2, wherein additional pumping means (141, 143) for pumping said inner enclosure (100) are provided, which are adapted to vacuum said evaporation chamber (100).

17. The evaporation cell (10) according to claim 2, wherein exhausting means (141, 142) for exhausting said inner enclosure (100) are provided, which are adapted to reaerate said evaporation chamber (100).

18. The evaporation cell (10) according to claim 2, further including a loading chamber (200) adjacent to the evaporation chamber (100) for the engagement and the disengagement of said crucible (110) into/from the evaporation chamber (100), said loading chamber (200) being in communication with the evaporation chamber (100) through said insertion opening (12).
